(19) United States
(12) Patent Application Publication
(10) Pub. No.: US 2026/0182434 A1
(43) Pub. Date: Jun. 25, 2026

(54) METHOD FOR MANUFACTURING STRUCTURAL BODY AND SEMICONDUCTOR DEVICE

(71) Applicant: Kioxia Corporation, Tokyo (JP)

(72) Inventor: Shinichi NAKAO, Yokkaichi (JP)

(73) Assignee: Kioxia Corporation, Tokyo (JP)

(21) Appl. No.: 19/324,379

(22) Filed: Sep. 10, 2025

(30) Foreign Application Priority Data
Dec. 20, 2024 (JP) 2024-225054

(51) Int. Cl. H01L 21/56; H01L 23/29; H01L 25/18; H10B 80/00; H10D 80/30

(52) U.S. Cl. CPC H10W 74/01; H10W 74/476; H10B 80/00; H10D 80/30; H10W 90/00

(57) ABSTRACT

A method for manufacturing a semiconductor device includes: forming a structural body on a substrate, the structural body comprising a recess with respect to a first surface of the structural body; providing a first portion of a plurality of insulating particles inside the recess and below the first surface; annealing the first portion of the insulating particles inside the recess; and filling gaps between the first portion of the insulating particles with a liquid insulator.

### CROSS-REFERENCE TO RELATED APPLICATION(S)

This application is based upon and claims the benefit of priority from Japanese Patent Application No. 2024-225054, filed Dec. 20, 2024, the entire contents of which are incorporated herein by reference.

### FIELD

Embodiments described herein relate generally to a method for manufacturing a structural body and a semiconductor device.

### BACKGROUND

A NAND flash memory is known as a semiconductor memory device. The NAND flash memory includes a memory cell array and a control circuit for the memory cell array. As a manufacturing method for a semiconductor memory device, a method in which memory cell array chips and control circuit chips are formed on different substrates, and then the substrates are bonded together is known. In a method for manufacturing a semiconductor device in which memory cell array chips are bonded to a substrate on which control circuit chips are formed, there is a large gap between the memory cell array chips adjacent to each other and thus it is necessary to fill this gap.

### DESCRIPTION OF THE DRAWINGS

FIG. 1 is a cross-sectional view illustrating a structural body according to an embodiment of the disclosure.

FIG. 2 is a cross-sectional view illustrating a method for manufacturing a structural body according to the embodiment of the disclosure.

FIG. 3 is a cross-sectional view illustrating a method for manufacturing a structural body according to the embodiment of the disclosure.

FIG. 4 is a cross-sectional view illustrating a method for manufacturing a structural body according to the embodiment of the disclosure.

FIG. 5 is a cross-sectional view illustrating a method for manufacturing a structural body according to the embodiment of the disclosure.

FIG. 6 is a cross-sectional view illustrating a semiconductor device according to an embodiment of the disclosure.

FIG. 7 is a cross-sectional view illustrating the semiconductor device according to the embodiment of the disclosure.

### DETAILED DESCRIPTION

Embodiments provide a method for manufacturing a structural body and a semiconductor device that increases crack resistance.

In general, according to one embodiment, a method for manufacturing a semiconductor device includes: forming a structural body on a substrate, the structural body comprising a recess with respect to a first surface of the structural body; providing a first portion of a plurality of insulating particles inside the recess and below the first surface; annealing the first portion of the insulating particles inside the recess; and filling gaps between the first portion of the insulating particles with a liquid insulator.

Hereinafter, a method for manufacturing a structural body and a semiconductor device according to embodiments will be described in detail with reference to the accompanying drawings. In the following description, elements having substantially the same functions and configurations are denoted by the same reference signs or reference signs obtained by adding alphabetic characters after the same reference signs, and are duplicately described only when necessary. The embodiments described below exemplify a device and a method for embodying the technical thought of the embodiments. Various changes may be made to the embodiments without departing from the spirit of the disclosure. These embodiments and modifications thereof are included in the scope of the disclosure described in the claims and equivalents thereof.

In order to further clarify the description, the drawings may illustrate widths, thicknesses, shapes, and the like in a schematic manner as compared to an actual aspects, but the drawings are merely examples and do not limit the interpretation of the present disclosure. In the specification and the drawings, elements having the same functions as those already described with respect to preceding drawings are denoted by the same reference signs, and duplicate descriptions thereof may be omitted.

In the present specification, expressions such as “α includes A, B or C” does not exclude cases in which α includes a plurality of combinations from A through C, unless otherwise specified. In addition, these expressions do not exclude cases in which α includes other elements.

The embodiments below can be combined with each other, as long as no technical inconsistency occurs.

### FIRST EMBODIMENT

### Configuration of Structural Body

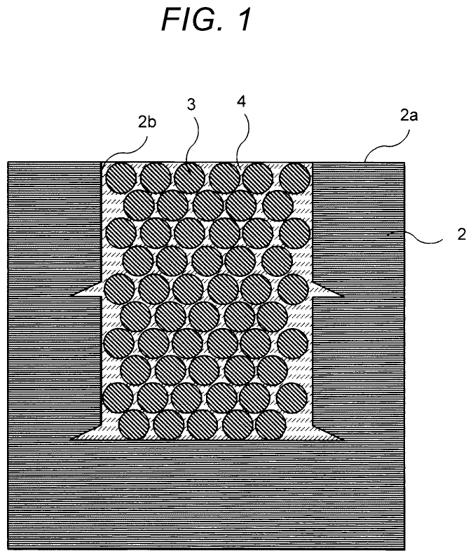

A configuration of a structural body of a semiconductor device according to the present embodiment will be described using FIG. 1. FIG. 1 is a cross-sectional view illustrating a structural body 1 of the semiconductor device according to the present embodiment.

As illustrated in FIG. 1, the structural body 1 includes a layer 2, insulating particles 3, and an insulator 4. The layer 2 includes a recess 2b having an opening in a first surface 2a. A plurality of insulating particles 3 are provided inside the recess 2b of the layer 2. The insulator 4 is provided in a region excluding the plurality of insulating particles 3 inside the recess 2b of the layer 2. The insulator 4 fills gaps between the plurality of insulating particles 3 inside the recess 2b of the layer 2.

Preferably, the insulating particles 3 have a spherical shape and have an average particle size of 100 nm or more and 1000 nm or less. The insulating particles 3 may have a uniform particle size or a plurality of particle sizes. The total volume of the insulating particles 3 is preferably in a range from 40 volume% or more and 80 volume% or less with respect to the volume of the recess 2b of the layer 2. When the average particle size of the insulating particles 3 increases, the number of contacts between the insulating particles 3 adjacent to each other decreases, the gaps between the insulating particles 3 adjacent to each other increase, and the cohesiveness of the insulating particles 3 as aggregate may decrease. When the average particle size of the insulating particles 3 decreases, the number of contacts between the insulating particles 3 increases, deformation due to a stress cannot be tolerated, and a mechanical strength may be impaired.

Preferably, the insulating particles 3 do not protrude from the first surface 2a of the layer 2. The insulating particles 3 are preferably embedded up to an upper end (the first surface 2a) of the recess 2b or below the upper end. FIG. 1 illustrates a configuration in which the tangent planes of the plurality of insulating particles 3 are flush with the first surface 2a of the layer 2. However, not limited to the above, the number of the plurality of insulating particles 3 may be less than the above. In that case, the plurality of insulating particles 3 are stacked from the bottom of the recess 2b and need not reach to the first surface 2a of the layer 2. The insulating particles 3 are not necessarily provided at an upper portion of the recess 2b. Preferably, a region in the upper portion of the recess 2b in which the insulating particles 3 are not provided is within the average particle size of the insulating particles 3 from the upper end (the first surface 2a) of the recess 2b.

The insulating particles 3 may contain silicon and oxygen, and may contain silicon oxide (SiO₂). However, not limited to the above, the insulating particles 3 may contain alumina (Al₂O₃), zirconia (ZrO₂), silicon nitride (SiN), or aluminum nitride (AlN). The surfaces of the insulating particles 3 are preferably hydrophilic.

Preferably, the insulator 4 does not protrude from the first surface 2a of the layer 2. The insulator 4 is preferably a material in which polymerization is completed by low-temperature baking. For example, when copper wiring is present at the layer 2, or in consideration of the crack resistance of the insulator 4, a material in which polymerization is completed at 400° C. or lower is preferable. When the content rate of the insulator 4 is high, the crack resistance of the insulator 4 may be reduced. When the content rate of the insulator 4 is low, the mechanical strength may be impaired.

The insulator 4 may be a spin-on-dielectric (SOD) material. The insulator 4 may contain silicon, oxygen, and hydrogen, and may contain hydrogen silsesquioxane. However, not limited to the above, the insulator 4 may contain methyl silsesquioxane, organosiloxane, or polysilazane.

The size of the recess 2b, for example, the width or depth thereof is 10μm or more. In FIG. 1, the recess 2 b is a bottomed hole having an opening in the first surface 2a of the layer 2. However, not limited to the above, the recess 2b may be a portion between projections projecting from the bottom surface of the recess 2b, and need not be surrounded by the projections. The recess 2b is filled with the insulating particles 3 and the insulator 4. The first surface 2a of the layer 2 is preferably hydrophobic. The inner surfaces and the bottom surface of the recess 2b are preferably hydrophilic.

There may be minute slits or gaps in the inner surfaces and the bottom surface of the recess 2b. The size of the minute slits or gaps, for example, the width or depth thereof is less than the average particle size of the insulating particles 3. Thus, the slits or gaps are filled with the insulator 4 only.

The structural body 1 according to the present embodiment can increase the crack resistance because the recess 2b having a large volume is filled with the plurality of insulating particles 3 and the insulator 4. With this configuration, an efficiency in manufacturing the semiconductor device according to the present embodiment can be increased.

### Method for Manufacturing Structural Body

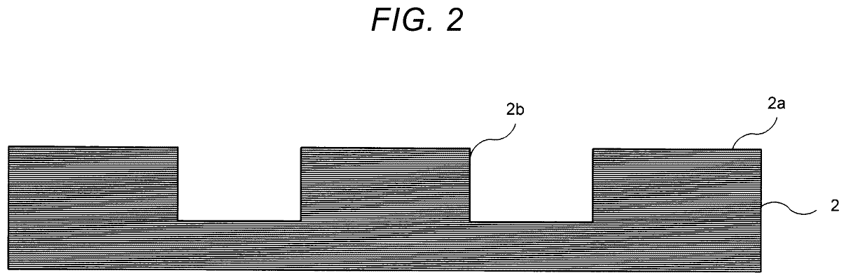

FIGS. 2 to 5 are cross-sectional views illustrating a method for manufacturing a structural body of a semiconductor device according to the present embodiment.

As illustrated in FIG. 2, the recess 2b is formed in the first surface 2a of the layer 2. The recess 2b may be formed by disposing a plurality of projections on the bottom surface of the recess 2b. For example, the recess 2b may be formed by disposing memory array chips on a control circuit board which will be described below. The first surface 2a of the layer 2 is preferably hydrophobic. The first surface 2a may have a liquid repellent property through silylation treatment with a wet apparatus. The inner surfaces and the bottom surface of the recess 2b of the layer 2 are preferably hydrophilic. The inner surfaces and the bottom surface of the recess 2b may have a hydrophilic property by removing the above-described silylation through plasma treatment.

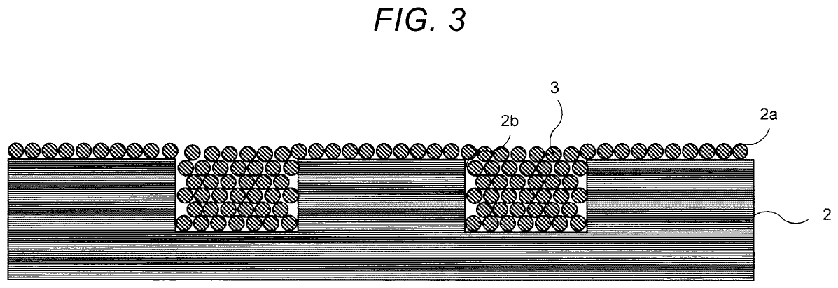

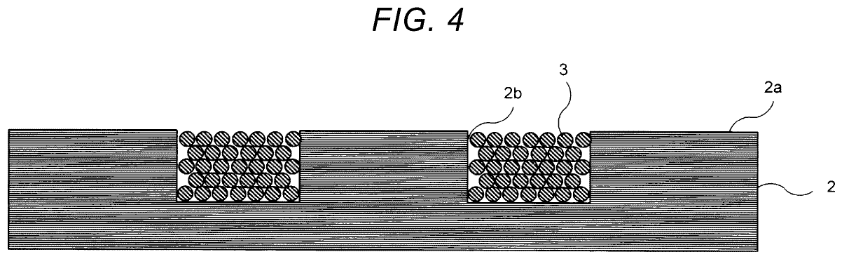

Next, as illustrated in FIG. 3, the insulating particles 3 are applied to the inside of the recess 2b. The insulating particles 3 may be applied to the first surface 2a and the inside of the recess 2b of the layer 2 with an applicator and then, among the insulating particles 3, a part of the insulating particles 3 provided on the first surface 2a may be removed as illustrated in FIG. 4. The part of the insulating particles 3 may be removed, for example, by a low-load brush cleaning or low-load chemical mechanical polishing (CMP) apparatus.

In the method for manufacturing a structural body of a semiconductor device according to the present embodiment, the insulating particles 3 provided on the first surface 2a are removed before an annealing process described below. In the case of removing the insulating particles 3 provided on the first surface 2a after the annealing process, the film thickness of the insulating particles 3 on the first surface 2a is the same as, for example, the depth of the recess 2b. The amount of the insulating particles 3 equivalent to the insulating particles 3 applied to the inside of the recess 2b having a width or depth of, for example, 10μm or more forms a thick film and requires a long polishing or etching time, which causes a difficulty in manufacturing. In addition, in the case of removing the insulating particles 3 after annealing, for example, with a chemical mechanical polishing apparatus, gaps between the insulating particles 3 may be clogged with abrasive particles. In the case of removing the insulating particles 3 after annealing, for example, by reactive ion etching (RIE), the progress speed of the etching may vary depending on the presence or absence of the insulating particles 3. So, it may become very difficult to flatly remove only the particle layer on the first surface 2a. Since the insulating particles 3 are not bound to each other before the annealing process, the insulating particles 3 on the first surface 2a can be easily removed even when the film thickness of the insulating particles 3 on the first surface 2a is thick.

The method is not limited to applying the insulation particles 3 to the inside of the recess 2b and then removing the insulating particles 3 provided on the first surface 2a as illustrated in FIGS. 3 and 4, but the insulating particles 3 may be embedded only inside the recess 2b of the layer 2 as illustrated in FIG. 4. The insulating particles 3 may be embedded only inside the recess 2b of the layer 2, for example, with a CMP apparatus that supplies the insulating particles 3 instead of slurry. At this time, the insulating particles 3 are not deposited on the first surface 2a of the layer 2 as illustrated in FIG. 3. Since the first surface 2a of the layer 2 is hydrophobic and the inner surfaces and the bottom surface of the recess 2b are hydrophilic, the insulating particles 3 whose surfaces are hydrophilic can be easily embedded inside the recess 2b of the layer 2.

Next, the insulating particles 3 provided inside the recess 2b are annealed. Annealing conditions may be set in accordance with the configurations of the insulating particles 3, the insulator 4, and the layer 2. For example, when copper wiring is present at the layer 2, or in consideration of the crack resistance of the insulator 4, annealing may be performed at 400° C. or lower.

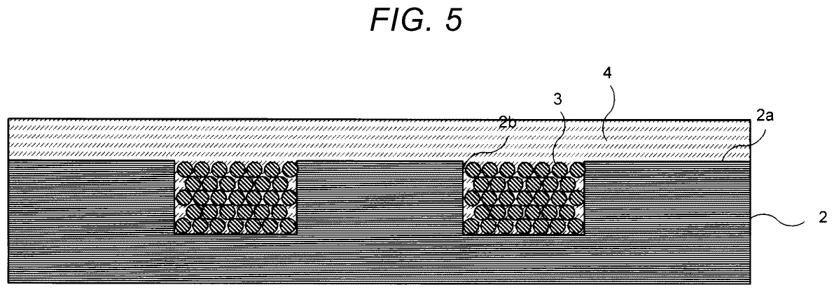

Next, as illustrated in FIG. 5, the insulator 4 is applied to the first surface 2a and the inside of the recess 2b of the layer 2. The liquid material of the insulator 4 is applied to the first surface 2a and the inside of the recess 2b of the layer 2 with a spin coating apparatus. The liquid material of the insulator 4 enters gaps between the insulating particles 3 inside the recess 2b and fills the inside of the recess 2b. Since the surfaces of the insulating particles 3 and the inner surfaces and the bottom surface of the recess 2b of the layer 2 are hydrophilic, the liquid material of the insulator 4 can easily fill the inside of the recess 2b of the layer 2. Before the insulator 4 is applied, for example, surface control using a surfactant may be performed on the surfaces of the insulating particles 3 and the inner surfaces and the bottom surface of the recess 2b of the layer 2 so as to enhance the hydrophilic property and prevent the formation of voids. After the liquid material of the insulator 4 is applied, the insulator 4 may be subjected to reflow by low-temperature heating. In addition, by adjusting the magnitude of the molecular weight of the liquid material of the liquid insulator 4, the liquid material of the insulator 4 can easily fill the inside of the recess 2b of the layer 2, and the formation of voids inside the recess 2b can be prevented.

The material of the insulator 4 applied to the first surface 2a and the inside of the recess 2b of the layer 2 may form the insulator 4 through polymerization by low-temperature baking. Low-temperature baking conditions may be appropriately set in accordance with the material of the insulator 4. For example, when copper wiring is present at the layer 2, or in consideration of the crack resistance of the insulator 4, the low-temperature baking may be performed at 400° C. or lower.

The insulator 4 formed on the first surface 2a of the layer 2 may be removed. The structural body 1 illustrated in FIG. 1 can be formed by removing the insulator 4 formed on the first surface 2a of the layer 2 by a CMP apparatus or dry etching until the first surface 2a of the layer 2 is exposed. The method for manufacturing a structural body of a semiconductor device according to the present embodiment can easily fill the recess 2b having a large volume, and can also easily flatten the first surface 2a of the layer 2.

### SECOND EMBODIMENT

### Configuration of Semiconductor Device

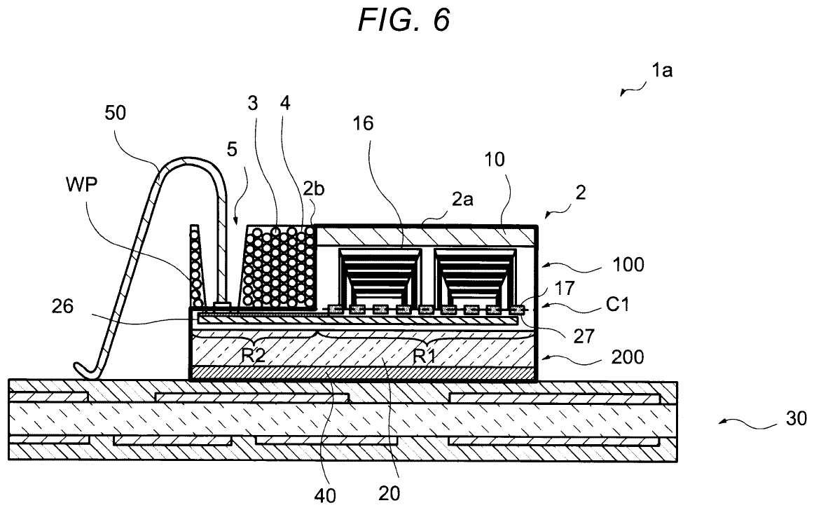

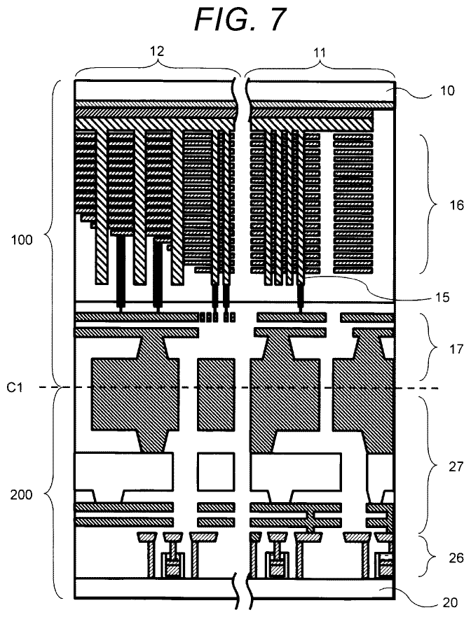

A configuration of a semiconductor device 1a according to the present embodiment will be described using FIGS. 6 and 7. FIG. 6 is a cross-sectional view illustrating an overall configuration of the semiconductor device 1a. FIG. 7 is an enlarged cross-sectional view illustrating a basic configuration of the semiconductor device 1a.

As illustrated in FIG. 6, the semiconductor device 1a is a bonded substrate and includes a memory cell array chip 100 and a control circuit (CMOS circuit) chip 200. The memory cell array chip 100 and the control circuit chip 200 are connected at a connection surface C1. On an upper surface of the control circuit chip 200, a second region R2, which is different from a first region R1 provided with the memory cell array chip 100, is embedded with the insulating particles 3 and the insulator 4. In FIG. 6, a portion (solid line) in which the memory cell array chip 100 according to the second embodiment is bonded to a substrate on which the control circuit chip 200 is formed corresponds to the layer 2 including the recess 2b of the first embodiment. A first surface 2a of the memory cell array chip 100 on a substrate 10 side is preferably hydrophobic. The side surfaces of the memory cell array chip 100 and the second region R2 of the control circuit chip 200 are preferably hydrophilic.

In the semiconductor device 1a, the control circuit chip 200 side is fixed to a wiring substrate 30 via an adhesive layer 40. The wiring substrate 30 may be a printed wiring board or an interposer including a wiring layer and an insulation layer. The insulating particles 3 and the insulator 4 of the semiconductor device 1a are formed with a through-hole 5 that exposes the second region R2 of the control circuit chip 200. A bonding wire 50 is disposed in the through-hole 5. The bonding wire 50 electrically connects a metal pad WP of the control circuit chip 200 and the wiring substrate 30 via the through-hole 5.

In the present embodiment, an example in which one semiconductor device 1a is disposed at the wiring substrate 30 is described. However, not limited to the above, a plurality of semiconductor devices 1a may be disposed at the wiring substrate 30. For example, the plurality of semiconductor devices 1a may be arranged side-by-side or may be stacked in a stepwise manner so as to expose a connection portion of the bonding wire 50.

### Structure of Memory Cell Array Chip

As illustrated in FIG. 7, the memory cell array chip 100 includes a plurality of electrode layers 16 and a memory-side wiring layer 17. The electrode layers 16 are stacked alternately with a plurality of insulation layers one-by-one on the substrate 10. Semiconductor pillars 15 are disposed in a direction perpendicular to the substrate 10 so as to penetrate the electrode layers 16 stacked. Each of the semiconductor pillars 15 is combined with the electrode layers 16 via the insulation layers to function as a plurality of transistors including memory cells. That is, the transistors including the memory cells are three-dimensionally disposed in a memory cell array region 11 (an upper right part of FIG. 7). One end (the substrate 10 side) of the semiconductor pillar 15 is electrically connected to a source line and the other end (the side opposite to the substrate 10) is electrically connected to the memory-side wiring layer 17 including a bit line BL. Connection terminals to be connected to the control circuit chip 200 are disposed at a connection surface C1 of the memory-side wiring layer 17.

On the substrate, a contact region 12 (an upper left part of FIG. 7) is disposed side by side with the memory cell array region 11. In the contact region 12, the terminal portions of the electrode layers 16 are drawn stepwise. Each of the terminal portions is connected to perpendicular wiring via a contact hole opened to an insulation film. The perpendicular wiring is electrically connected to the memory-side wiring layer 17 and connected to the control circuit chip 200 via the connection terminals.

### Structure of Control Circuit Chip

As illustrated in FIG. 7, the control circuit chip 200 includes a substrate 20, a plurality of transistors 26 constituting a control circuit, and circuit-side wiring layer 27. The transistors 26 are formed at the substrate 20 and are electrically connected to the circuit-side wiring layer 27 on a side opposite to the substrate 20. Connection terminals to be connected to the memory cell array chip 100 are disposed at the connection surface C1 of the circuit-side wiring layer 27. The substrate 20 may be a semiconductor wafer such as a silicon substrate.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A method for manufacturing a semiconductor device, comprising:
forming a structural body on a substrate, the structural body comprising a recess with respect to a first surface of the structural body;
providing a first portion of a plurality of insulating particles inside the recess and below the first surface;
annealing the first portion of the insulating particles inside the recess; and
filling gaps between the first portion of the insulating particles with a liquid insulator.

2. The method for manufacturing a semiconductor device according to claim 1, further comprising using a chemical mechanical polishing apparatus to provide a second portion of the insulating particles inside the recess.

3. The method for manufacturing a semiconductor device according to claim 1, further comprising using an applicator to overlay the structural body with the insulating particles.

4. The method for manufacturing a semiconductor device according to claim 3, before the annealing, further comprising removing a second portion of the insulating particles provided above or along the first surface, using a low-load brush cleaning or chemical mechanical polishing apparatus.

5. A method for manufacturing a semiconductor device, comprising:
forming a structural body on a substrate, the structural body comprising a recess with respect to a first surface of the structural body;
providing, over the structural body, a plurality of insulating particles using an applicator;
removing a second portion of the insulating particles provided above or along the first surface using a low-load brush cleaning or chemical mechanical polishing apparatus; and
filling gaps between a first portion of the insulating particles inside the recess with a liquid insulator.

6. The method for manufacturing a semiconductor device according to claim 5, further comprising annealing the first portion of the insulating particles inside the recess after the removing.

7. A method for manufacturing a semiconductor device, comprising:
forming a structural body on a substrate, the structural body comprising a recess with respect to a first surface of the structural body;
providing a plurality of insulating particles inside the recess based on a chemical mechanical polishing process; and
filling gaps between the insulating particles inside the recess with a liquid insulator.

8. The method for manufacturing a semiconductor device according to claim 1, wherein the structural body comprises a memory cell array chip and a control circuit chip.

9. The method for manufacturing a semiconductor device according to claim 1, wherein the insulating particles have a spherical shape and have an average particle size between 100nm and 1000nm.

10. The method for manufacturing a semiconductor device according to claim 1, wherein the insulating particles have a uniform particle size.

11. The method for manufacturing a semiconductor device according to claim 1, wherein the insulating particles have a plurality of particle sizes.

12. The method for manufacturing a semiconductor device according to claim 1, wherein a total volume of the first portion of the insulating particles is between 40 volume% and 80 volume% with respect to a volume of the recess.
